(19) United States
(12) Patent Application Publication
(10) Pub. No.: US 2006/0210712 A1
(43) Pub. Date: Sep. 21, 2006

(54) Method of depositing thin film on substrate using impulse ALD process

(76) Inventors: Young Hoon Park, Pyungtaek-city (KR); Sahng Kyu Lee, Pyungtaek-city (KR); Ki Hoon Lee, Pyungtaek-city (KR); Tae Wook Seo, Pyungtaek-city (KR)

Correspondence Address: CANTOR COLBURN, LLP, 55 GRIFFIN ROAD SOUTH, BLOOMFIELD, CT, 06002, US

(21) Appl. No.: 11/377,153

(22) Filed: Mar. 16, 2006

(30) Foreign Application Priority Data
Mar. 16, 2005 (KR) 10-2005-0021875

(51) Int. Cl. C23C 16/00

(52) U.S. Cl. 427/248.1

(57) ABSTRACT

Provided is a method of depositing a thin film on a substrate using an impulse feeding process. The method includes performing a second reaction gas continuous feeding process of continuously feeding a second reaction gas into a chamber in which the substrate is installed, and performing a number of times, during the second reaction gas continuous feeding process, a process cycle including a first reaction gas feeding process of feeding a first reaction gas into the chamber and a first reaction gas purge process of purging the first reaction gas that is not adhered onto the substrate. The second reaction gas continuous feeding process includes a second reaction gas impulse process of feeding the second reaction gas at an impulse flow rate greater than a basic flow rate during the first reaction gas purge process.

### CROSS-REFERENCE TO RELATED PATENT APPLICATION

This application claims the benefit of Korean Patent Application No. 10-2005-0021875, filed on Mar. 16, 2005, in the Korean Intellectual Property Office, the disclosure of which is incorporated herein in its entirety by reference.

### BACKGROUND OF THE INVENTION

1. Field of the Invention

The present invention relates to a thin film deposition method, and more particularly, to a method of efficiently depositing a thin film on a substrate using an impulse feeding process.

2. Description of the Related Art

A current trend in the semiconductor industry is to make an ultrafine circuit linewidth and to constantly lower a thin film deposition temperature, achieving desired results in many processes. An atomic layer deposition (ALD) process is a widely known representative process that achieves the desired results.

Efforts to develop the ALD process were initiated in the semiconductor industry in the late 90s, and the ALD process has been actively developed up to now. However, the ALD process, in the traditional and narrow meaning, where alternating pulses using two kinds of reaction gases are created and an operation of interposing a purge gas between the pulses (purge operation) is repeated, is not effective when forming thin films. Such thin films include TiN and Ti. For example, when a TiN thin film is deposited using a traditional single-wafer ALD process, the purity and step coverage of the thin film are excellent, but productivity is two low.

### SUMMARY OF THE INVENTION

The present invention provides a method of depositing a thin film on a substrate, which can enhance the purity of the thin film while reducing the deposition time.

According to an aspect of the present invention, there is provided a method of depositing a thin film on a substrate, the method including: performing a second reaction gas continuous feeding process of continuously feeding a second reaction gas into a chamber in which the substrate is installed; and performing a number of times, during the second reaction gas continuous feeding process, a process cycle including a first reaction gas feeding process of feeding a first reaction gas into the chamber and a first reaction gas purge process of purging the first reaction gas that is not adhered onto the substrate, wherein the second reaction gas continuous feeding process includes a second reaction gas impulse process of feeding the second reaction gas at an impulse flow rate greater than a basic flow rate during the first reaction gas purge process.

According to another aspect of the present invention, there is provided a method of depositing a thin film on a substrate, the method including: simultaneously performing a second reaction gas continuous feeding process of continuously feeding a second reaction gas into a chamber in which the substrate is installed and a purge gas continuous feeding process of continuously feeding a purge gas onto the substrate; and performing a number of times, during the second reaction gas continuous feeding process, a process cycle including a first reaction gas feeding process of feeding a first reaction gas into the chamber and a first reaction gas purge process of purging the first reaction gas that is not adhered onto the substrate, wherein the second reaction gas continuous feeding process includes a second reaction gas impulse process of feeding the second reaction gas at an impulse flow rate greater than a basic flow rate during the first reaction gas purge process; and the purge gas continuous feeding process includes a purge gas impulse process of feeding the purge gas at an impulse flow rate greater than a basic flow rate of a flow from the end of the second reaction impulse process to the start of a first reaction gas feeding process of the next process cycle.

According to another aspect of the present invention, there is provided a method of depositing a thin film on a substrate, the method including: simultaneously performing a second reaction gas discontinuous feeding process of discontinuously feeding a second reaction gas into a chamber in which a substrate is installed and a purge gas continuous feeding process of continuously feeding a purge gas onto the substrate; and performing a number of times, during the second reaction gas discontinuous feeding process, a process cycle including a first reaction gas feeding process of feeding a first reaction gas into the chamber and a first reaction gas purge process of purging the first reaction gas that is not adhered onto the substrate, wherein the second reaction gas discontinuous feeding process includes a second reaction gas impulse process of feeding the second reaction gas at an impulse flow rate greater than a basic flow rate during the first reaction gas purge process, and a second reaction gas feeding stop process of performed from the end of the second reaction gas impulse process to the start of a first reaction gas feeding process of the next process cycle; and the purge gas continuous feeding process includes a purge gas impulse process of feeding the purge gas at an impulse flow rate greater than a basic flow rate, preformed simultaneously with the second reaction gas feeding stop process.

According to another aspect of the present invention, there is provided a method of depositing a thin film on a substrate, the method including: performing a process cycle a number of times, the process cycle including a first reaction gas feeding process of feeding a first reaction gas into a chamber in which a substrate is installed, a first reaction gas purge process of purging the first reaction gas that is not adhered onto the substrate, a second reaction gas feeding process of feeding a second reaction gas into the chamber, and a second reaction gas purge process of purging reaction by-products produced by reaction with the first reaction gas floating over the substrate or the second reaction gas not reacting with the first reaction gas adhered onto the substrate; and performing a purge gas continuous feeding process of continuously feeding a purge gas onto the substrate during the performing of process cycles, wherein the purge gas continuous feeding process includes a purge gas impulse process of feeding the purge gas onto the substrate at an impulse flow rate greater than a basic flow rate of a flow, the purge gas impulse process starting after the first reaction gas feeding process and ending before the second reaction gas feeding process.

According to another aspect of the present invention, there is provided a method of depositing a thin film on a substrate, the method including: performing a process cycle a number of times, the process cycle including a first reaction gas feeding process of feeding a first reaction gas into a chamber in which a substrate is installed, a first reaction gas purge process of purging the first reaction gas that is not adhered onto the substrate, a second reaction gas feeding process of feeding a second reaction gas into the chamber, and a second reaction gas purge process of purging reaction by-products produced by reaction with the first reaction gas floating over the substrate or the second reaction gas not reacting with the first reaction gas adhered onto the substrate; and performing a purge gas continuous feeding process of continuously feeding a purge gas onto the substrate during the performing of the process cycles. The purge gas continuous feeding process includes: a first purge gas impulse process of feeding a purge gas at an impulse flow rate greater than a basic flow rate of a flow, the first purge gas impulse process staring after the first reaction gas feeding process ending before the second reaction gas feeding process; and a second purge gas impulse process of feeding a purge gas at an impulse flow rate greater than a basic flow rate of a flow, the second purge gas impulse process starting after the second reaction gas feeding process and ending before a first reaction gas feeding process of the next process cycle.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a process sequence of a thin film deposition method according to an embodiment of the present invention;

FIG. 2 illustrates a process sequence of a thin film deposition method according to another embodiment of the present invention;

FIG. 3 illustrates a process sequence of a thin film deposition method according to another embodiment of the present invention;

FIG. 4 illustrates a process sequence of a thin film deposition method according to another embodiment of the present invention; and

FIG. 5 illustrates a process sequence of a thin film deposition method according to another embodiment of the present invention.

### DETAILED DESCRIPTION OF THE INVENTION

The present invention will now be described more fully with reference to the accompanying drawings, in which exemplary embodiments of the invention are shown.

FIG. 1 illustrates a process sequence of a thin film deposition method according to an embodiment of the present invention.

Referring to FIG. 1, the thin film deposition method includes: performing a second reaction gas continuous feeding process S12 of continuously feeding a second reaction gas into a chamber in which a substrate is installed; and performing a number of times, during the second reaction gas continuous feeding process S12, a process cycle including a first reaction gas feeding process S13a of feeding a first reaction gas into the chamber and a first reaction gas purge process S13b of purging the first reaction gas that is not adhered onto the substrate.

The second reaction gas continuous feeding process S12 includes a second reaction gas impulse process S12a of feeding the second reaction gas at an impulse flow rate greater than a basic flow rate during the first reaction gas purge process S13b.

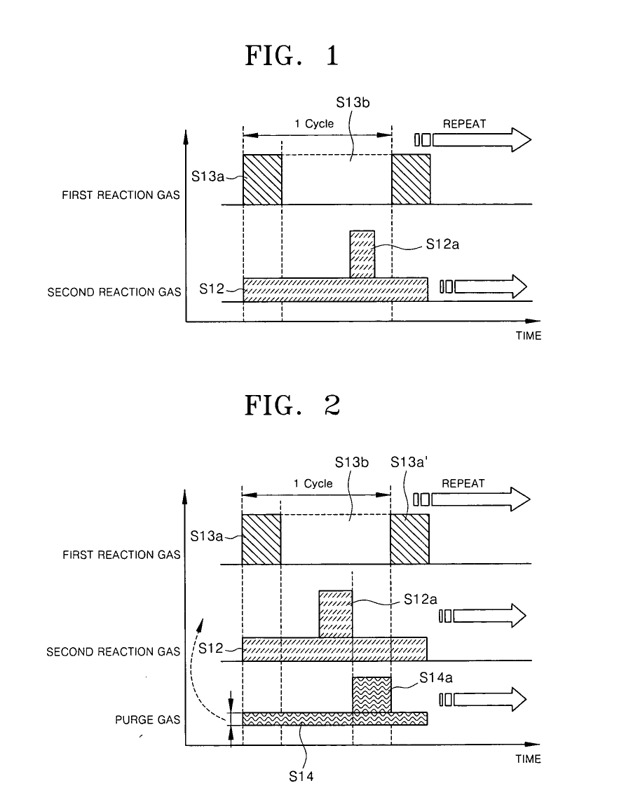

FIG. 2 illustrates a process sequence of a thin film deposition method according to another embodiment of the present invention.

Referring to FIG. 2, the thin film deposition method includes: simultaneously performing a second reaction gas continuous feeding process S12 of continuously feeding a second reaction gas into a chamber in which a substrate is installed and a purge gas continuous feeding process S14 of continuously feeding a purge gas onto the substrate; and performing a number of times, during the second reaction gas continuous feeding process S12, a process cycle including a first reaction gas 25 feeding process S13a of feeding a first reaction gas into the chamber and a first reaction gas purge process S13b of purging the first reaction gas that is not adhered onto the substrate.

The second reaction gas continuous feeding process S12 includes a second reaction gas impulse process S12a of feeding the second reaction gas at an impulse flow rate greater than a basic flow rate during the first reaction gas purge process S13b.

The purge gas continuous feeding process S14 includes a purge gas impulse process S14a of feeding the purge gas at an impulse flow rate greater than a basic flow rate of a flow from the end of the second reaction impulse process S12a to the start of a first reaction gas feeding process S13a′ of the next process cycle.

As described above, unlike the thin film deposition method of the embodiment of FIG. 1, thin film deposition method of the embodiment of FIG. 2 further includes: the purge gas continuous feeding process S14 performed during the process cycle; and the purge gas impulse process S14a performed from the end of the second reaction impulse process S12a to the start of a first reaction gas feeding process S13a′ of the next process cycle.

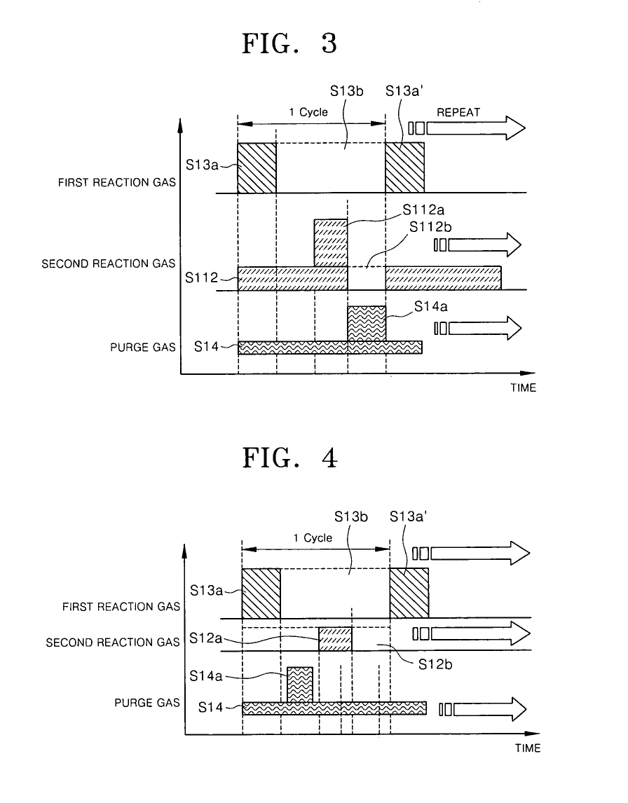

FIG. 3 illustrates a process sequence of a thin film deposition method according to another embodiment of the present invention.

Referring to FIG. 3, the thin film deposition method includes: simultaneously performing a second reaction gas discontinuous feeding process S112 of discontinuously feeding a second reaction gas into a chamber in which a substrate is installed and a purge gas continuous feeding process S14 of continuously feeding a purge gas onto the substrate; and performing a number of times, during the second reaction gas discontinuous feeding process S12, a process cycle including a first reaction gas feeding process S13a of feeding a first reaction gas into the chamber and a first reaction gas purge process S13b of purging the first reaction gas that is not adhered onto the substrate.

The second reaction gas discontinuous feeding process S112 includes: a second reaction gas impulse process S112a of feeding the second reaction gas at an impulse flow rate greater than a basic flow rate during the first reaction gas purge process S13b; and a second reaction gas feeding stop process S112b performed from the end of the second reaction gas impulse process S112a to the start of a first reaction gas feeding process S13a′ of the next process cycle.

The purge gas continuous feeding process S14 includes a purge gas impulse process S14a of feeding the purge gas at an impulse flow rate greater than a basic flow rate, performed simultaneously with the second reaction gas feeding stop process S112b.

As described above, unlike the thin film deposition method of the embodiment of FIG. 2, the thin film deposition method of the embodiment of FIG. 3 includes: the second reaction gas discontinuous feeding process S112 including the second reaction gas impulse process S112a and the second reaction gas feeding stop process S112b; and the purge gas continuous feeding process S14 including the purge gas impulse process S14a performed simultaneously with the second reaction gas feeding stop process S112b.

FIG. 4 illustrates a process sequence of a thin film deposition method according to another embodiment of the present invention.

Referring to FIG. 4, the thin film deposition method includes: performing a number of times a process cycle including a first reaction gas feeding process S13a of feeding a first reaction gas into a chamber in which a substrate is installed, a first reaction gas purge process S13b of purging the first reaction gas that is not adhered onto the substrate, a second reaction gas feeding process 12a of feeding a second reaction gas into the chamber, and a second reaction gas purge process S12b of purging reaction by-products produced by reaction with the first reaction gas floating over the substrate or the second reaction gas not reacting with the first reaction gas adhered onto the substrate; and performing a purge gas continuous feeding process S14 of continuously feeding a purge gas onto the substrate during the repeated process cycles.

The purge gas continuous feeding process S14 includes a purge gas impulse process S14a of feeding the purge gas onto the substrate at an impulse flow rate greater than a basic flow rate of a flow. The purge gas impulse process S14a starts after the first reaction gas feeding process S13a and ends before the second reaction gas feeding process S12a.

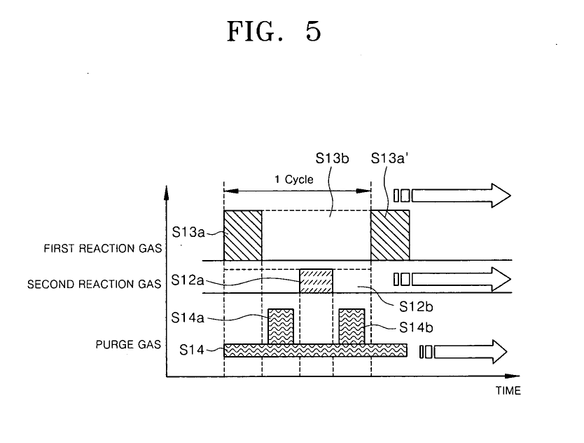

FIG. 5 illustrates a process sequence of a thin film deposition method according to another embodiment of the present invention.

Referring to FIG. 5, the thin film deposition method includes: performing a number of times a process cycle including a first reaction gas feeding process S13a of feeding a first reaction gas into a chamber in which a substrate is installed, a first reaction gas purge process S13b of purging the first reaction gas that is not adhered onto the substrate, a second reaction gas feeding process 12a of feeding a second reaction gas into the chamber, and a second reaction gas purge process S12b of purging reaction by-products produced by reaction with the first reaction gas floating over the substrate or the second reaction gas not reacting with the first reaction gas adhered onto the substrate; and performing a purge gas continuous feeding process S14 of continuously feeding a purge gas onto the substrate during the repeated process cycles.

The purge gas continuous feeding process S14 includes: a first purge gas impulse process S14a of feeding a purge gas at an impulse flow rate greater than a basic flow rate of a flow, the first purge gas impulse process S14a starting after the first reaction gas feeding process S13a and ending before the second reaction gas feeding process S12a; and a second purge gas impulse process S14b of feeding a purge gas at an impulse flow rate greater than a basic flow rate of a flow, the second purge gas impulse process S14b starting after the second reaction gas feeding process S12a and ending before a first reaction gas feeding process S13a′ of the next process cycle.

As described above, unlike the thin film deposition method of the embodiment of FIG. 4, the thin film deposition method of the embodiment of FIG. 5 includes: the first purge gas impulse process S14a starting after the first reaction gas feeding process S13a and ending before the second reaction gas feeding process S12a; and the second purge gas impulse process S14b staring after the second reaction gas feeding process S12a and ending before a first reaction gas feeding process S13a′ of the next process cycle.

When compared to the conventional ALD thin film deposition method, the thin film deposition method of the above embodiments can provide an increased deposition speed, enhanced step coverage, and enhanced purity of the thin film due to the following three reasons.

The first reason is that the second reaction gas is fed continuously in the thin film deposition methods of the aforementioned embodiments in contrast with the conventional ALD thin film deposition method in which a second reaction gas is fed discontinuously. The second reason is that the purge gas is fed continuously or discontinuously. The third reason is that the second reaction gas and the purge gas are fed at the basic flow rates or at the impulse flow rates. Due to these three reasons, the non-reaction gas or the reaction by-product remaining on the substrate can be rapidly flowed to the outside of the substrate and a thermolytic substitution reaction with the first reaction gas adhered onto the substrate can be performed densely and rapidly.

Examples of process applications for the above embodiments will now be described in detail.

In a process application, the first reaction gas is vaporized from a precursor liquid material containing a metallic element, or gas outputted from a compressed gas container. The second reaction gas is a reaction gas containing H (hydrogen). The thin film deposited using the first and second reaction gases is a thin film containing the above metallic element, such as a Ti thin film, a W thin film, a Ta thin film, and a Ru thin film.

In another process application, the first reaction gas is vaporized from a precursor liquid material containing a metallic element, or gas outputted from a compressed gas container. The second reaction gas is a reaction gas containing N (Nitrogen). The thin film deposited using the first and second reaction gases is a metal nitride thin film containing the above metallic element, such as a TiN thin film, a WN thin film, and a TaN thin film. For the TiN thin film, the first reaction gas is one selected from the group consisting of TICl₄, TEMATi, TDMAti, and a combination thereof, and the second reaction gas is NH₃.

Also, depending on the kind of the thin film and the environment of the process chamber, the deposition is performed at a chamber pressure of 0.1-10 torr and at a substrate temperature of 600° C. or below.

As described above, unlike the conventional ALD thin film deposition method, the thin film deposition method of the present invention further includes an impulse feeding process of feeding the second reaction gas or the purge gas at the impulse flow rate lower than the basic flow rate, thereby enhancing the deposition speed and characteristics of the thin film.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of depositing a thin film on a substrate, the method comprising:
performing a second reaction gas continuous feeding process of continuously feeding a second reaction gas into a chamber in which the substrate is installed; and
performing a number of times, during the second reaction gas continuous feeding process, a process cycle comprising a first reaction gas feeding process of feeding a first reaction gas into the chamber and a first reaction gas purge process of purging the first reaction gas that is not adhered onto the substrate,
wherein the second reaction gas continuous feeding process comprises a second reaction gas impulse process of feeding the second reaction gas at an impulse flow rate greater than a basic flow rate during the first reaction gas purge process.

2. A method of depositing a thin film on a substrate, the method comprising:
simultaneously performing a second reaction gas continuous feeding process of continuously feeding a second reaction gas into a chamber in which the substrate is installed and a purge gas continuous feeding process of continuously feeding a purge gas onto the substrate; and
performing a number of times, during the second reaction gas continuous feeding process, a process cycle comprising a first reaction gas feeding process of feeding a first reaction gas into the chamber and a first reaction gas purge process of purging the first reaction gas that is not adhered onto the substrate,
wherein the second reaction gas continuous feeding process comprises a second reaction gas impulse process of feeding the second reaction gas at an impulse flow rate greater than a basic flow rate during the first reaction gas purge process; and the purge gas continuous feeding process comprises a purge gas impulse process of feeding the purge gas at an impulse flow rate greater than a basic flow rate of a flow from the end of the second reaction impulse process to the start of a first reaction gas feeding process of the next process cycle.

3. A method of depositing a thin film on a substrate, the method comprising:
simultaneously performing a second reaction gas discontinuous feeding process of discontinuously feeding a second reaction gas into a chamber in which a substrate is installed and a purge gas continuous feeding process of continuously feeding a purge gas onto the substrate; and
performing a number of times, during the second reaction gas discontinuous feeding process, a process cycle comprising a first reaction gas feeding process of feeding a first reaction gas into the chamber and a first reaction gas purge process of purging the first reaction gas that is not adhered onto the substrate,
wherein the second reaction gas discontinuous feeding process comprises a second reaction gas impulse process of feeding the second reaction gas at an impulse flow rate greater than a basic flow rate during the first reaction gas purge process, and a second reaction gas feeding stop process performed from the end of the second reaction gas impulse process to the start of a first reaction gas feeding process of the next process cycle; and the purge gas continuous feeding process comprises a purge gas impulse process of feeding the purge gas at an impulse flow rate greater than a basic flow rate, performed simultaneously with the second reaction gas feeding stop process.

4. A method of depositing a thin film on a substrate, the method comprising:
performing a process cycle a number of times, the process cycle comprising a first reaction gas feeding process of feeding a first reaction gas into a chamber in which a substrate is installed, a first reaction gas purge process of purging the first reaction gas that is not adhered onto the substrate, a second reaction gas feeding process of feeding a second reaction gas into the chamber, and a second reaction gas purge process of purging reaction by-products produced by reaction with the first reaction gas floating over the substrate or the second reaction gas not reacting with the first reaction gas adhered onto the substrate; and
performing a purge gas continuous feeding process of continuously feeding a purge gas onto the substrate during the performing of the process cycles,
wherein the purge gas continuous feeding process comprises a purge gas impulse process of feeding the purge gas onto the substrate at an impulse flow rate greater than a basic flow rate of a flow, the purge gas impulse process starting after the first reaction gas feeding process and ending before the second reaction gas feeding process.

5. A method of depositing a thin film on a substrate, the method comprising:
performing a process cycle a number of times, the process cycle comprising a first reaction gas feeding process of feeding a first reaction gas into a chamber in which a substrate is installed, a first reaction gas purge process of purging the first reaction gas that is not adhered onto the substrate, a second reaction gas feeding process of feeding a second reaction gas into the chamber, and a second reaction gas purge process of purging reaction by-products produced by reaction with the first reaction gas floating over the substrate or the second reaction gas not reacting with the first reaction gas adhered onto the substrate; and
performing a purge gas continuous feeding process of continuously feeding a purge gas onto the substrate during the performing of the process cycles,
wherein the purge gas continuous feeding process comprises: a first purge gas impulse process of feeding a purge gas at an impulse flow rate greater than a basic flow rate of a flow, the first purge gas impulse process starting after the first reaction gas feeding process and ending before the second reaction gas feeding process; and a second purge gas impulse process of feeding a purge gas at an impulse flow rate greater than a basic flow rate of a flow, the second purge gas impulse process starting after the second reaction gas feeding process and ending before a first reaction gas feeding process of the next process cycle.

6. The method of claim 1, wherein the first reaction gas is vapor vaporized from a precursor liquid material containing a metallic element, or gas outputted from a compressed gas container; the second reaction gas is a reaction gas containing H (hydrogen); and the thin film deposited using the first and second reaction gases is a thin film containing the metallic element.

7. The method of claim 6, wherein the thin film is one of a Ti thin film, a W thin film, a Ta thin film, and a Ru thin film.

8. The method of claim 1, wherein the first reaction gas is vapor vaporized from a precursor liquid material containing a metallic element, or gas outputted from a compressed gas container; the second reaction gas is a reaction gas containing N (Nitrogen); and the thin film deposited using the first and second reaction gases is a metal nitride thin film containing the metallic element.

9. The method of claim 8, wherein the metal nitride thin film is one of a TiN thin film, a WN thin film, and a TaN thin film.

10. The method of claim 2, wherein the first reaction gas is vapor vaporized from a precursor liquid material containing a metallic element, or gas outputted from a compressed gas container; the second reaction gas is a reaction gas containing H (hydrogen); and the thin film deposited using the first and second reaction gases is a thin film containing the metallic element.

11. The method of claim 3, wherein the first reaction gas is vapor vaporized from a precursor liquid material containing a metallic element, or gas outputted from a compressed gas container; the second reaction gas is a reaction gas containing H (hydrogen); and the thin film deposited using the first and second reaction gases is a thin film containing the metallic element.

12. The method of claim 4, wherein the first reaction gas is vapor vaporized from a precursor liquid material containing a metallic element, or gas outputted from a compressed gas container; the second reaction gas is a reaction gas containing H (hydrogen); and the thin film deposited using the first and second reaction gases is a thin film containing the metallic element.

13. The method of claim 5, wherein the first reaction gas is vapor vaporized from a precursor liquid material containing a metallic element, or gas outputted from a compressed gas container; the second reaction gas is a reaction gas containing H (hydrogen); and the thin film deposited using the first and second reaction gases is a thin film containing the metallic element.

14. The method of claim 2, wherein the first reaction gas is vapor vaporized from a precursor liquid material containing a metallic element, or gas outputted from a compressed gas container; the second reaction gas is a reaction gas containing N (Nitrogen); and the thin film deposited using the first and second reaction gases is a metal nitride thin film containing the metallic element.

15. The method of claim 3, wherein the first reaction gas is vapor vaporized from a precursor liquid material containing a metallic element, or gas outputted from a compressed gas container; the second reaction gas is a reaction gas containing N (Nitrogen); and the thin film deposited using the first and second reaction gases is a metal nitride thin film containing the metallic element.

16. The method of claim 4, wherein the first reaction gas is vapor vaporized from a precursor liquid material containing a metallic element, or gas outputted from a compressed gas container; the second reaction gas is a reaction gas containing N (Nitrogen); and the thin film deposited using the first and second reaction gases is a metal nitride thin film containing the metallic element.

17. The method of claim 5, wherein the first reaction gas is vapor vaporized from a precursor liquid material containing a metallic element, or gas outputted from a compressed gas container; the second reaction gas is a reaction gas containing N (Nitrogen); and the thin film deposited using the first and second reaction gases is a metal nitride thin film containing the metallic element.
